(19) United States
(12) Patent Application Publication
(10) Pub. No.: US 2026/0052774 A1
(43) Pub. Date: Feb. 19, 2026

(54) ELECTRONIC DEVICE

(71) Applicant: InnoLux Corporation, Miao-Li County (TW)

(72) Inventors: Chung-Le CHEN, Miao-Li County (TW); Jhe-Ciou JHU, Miao-Li County (TW); Ai-Ling KUO, Miao-Li County (TW)

(21) Appl. No.: 19/269,315

(22) Filed: Jul. 15, 2025

(30) Foreign Application Priority Data
Aug. 16, 2024 (CN) 202411128003.3

(51) Int. Cl. H10D 86/60; G09G 3/00; H10D 86/40

(52) U.S. Cl. CPC H10D 86/60; G09G 3/006; H10D 86/421; G09G 2300/0819; G09G 2320/045; G09G 2360/144

(57) ABSTRACT

An electronic device includes a driving circuit having first, second, third, and fourth transistors. At least one of the second, third, and fourth transistors includes a conductive layer, a gate, and a semiconductor layer, with the conductive layer overlapping the gate in a normal direction. A temperature sensor detects the temperature of the driving circuit. A control chip receives the detected temperature and provides a first signal based thereon. The conductive layer receives the first signal to adjust a threshold bias voltage of the at least one of the second, third, and fourth transistors.

### CROSS REFERENCE TO RELATED APPLICATIONS

This application claims priority of China Patent Application No. 202411128003.3, filed on Aug. 16, 2024, the entirety of which is incorporated by reference herein.

### BACKGROUND OF THE INVENTION

### Field of the Invention

The present disclosure relates to an electronic device, and more particularly, it relates to an electronic device capable of modulating threshold voltage shift caused by temperature or brightness variations by applying an external signal to the conductive layer of a transistor.

### Description of the Related Art

It is well known that thin-film transistors (TFTs) may experience threshold voltage (VT) shifts due to variations in temperature or brightness. Such threshold voltage shifts can affect the performance of the TFTs, and consequently, the proper operation of electronic devices.

For example, in electronic devices used as displays, variations in temperature or brightness can cause threshold voltage shifts in TFTs within a gate-on-panel (GOP) circuit, which serves as a driving circuit. This can lead to problems such as leakage current in the TFTs, preventing the display from operating as intended.

### BRIEF SUMMARY OF THE INVENTION

An embodiment of the present invention provides an electronic device capable of modulating threshold voltage shift caused by temperature or brightness variations by applying an external signal to the conductive layer of a transistor, which can reduce the likelihood of threshold voltage shifts of the transistor that are caused by temperature or brightness variations, thereby ameliorating the aforementioned problems.

An embodiment of the present disclosure provides an electronic device, having a peripheral region. The electronic device comprising a driving circuit disposed in the peripheral region. The driving circuit comprises a first transistor, a second transistor, a third transistor, and a fourth transistor. The first transistor is coupled to a first node. The second transistor is configured to receive a first voltage and to charge the first node. The third transistor has a first terminal and a second terminal. The first terminal is coupled to the first node. The second terminal is coupled to ground. The fourth transistor has a first terminal and a second terminal. The first terminal is coupled to the first node. The second terminal is coupled to the ground. Of the second transistor, the third transistor, and the fourth transistor, at least one comprises a conductive layer, a gate, and a semiconductor layer. The conductive layer overlaps the gate in the normal direction of the electronic device. A temperature sensor is configured to detect the temperature of the driving circuit and to provide the detected temperature to a control chip. The control chip is configured to provide a first signal according to the different temperatures. The conductive layer (of the second transistor, the third transistor, and/or the fourth transistor) is configured to receive the first signal to adjust the threshold bias voltage of said transistor (of the second transistor, the third transistor, and/or the fourth transistor).

In addition, an embodiment of the present disclosure provides an electronic device, having a peripheral region. The electronic device comprises a driving circuit. The driving circuit is disposed in the peripheral region. The driving circuit comprises a first transistor, a second transistor, a third transistor, and a fourth transistor. The first transistor is coupled to a first node. The second transistor is configured to receive a first voltage and to charge the first node. The third transistor has a first terminal and a second terminal. The first terminal is coupled to the first node. The second terminal is coupled to a common ground. The fourth transistor has a first terminal and a second terminal. The first terminal is coupled to the first node. The second terminal is coupled to the common ground. Of the second transistor, the third transistor, and the fourth transistor, at least one comprises a conductive layer, a gate, and a semiconductor layer. The conductive layer overlaps the gate in the normal direction of the electronic device. A control chip is configured to receive a brightness driving signal that is representative of the brightness. The control chip is configured to provide a first signal according to the different brightness levels. The conductive layer is configured to receive the first signal to adjust the threshold bias voltage of said transistor (of the second transistor, the third transistor, and/or the fourth transistor).

### BRIEF DESCRIPTION OF THE DRAWINGS

The present invention can be more fully understood by reading the subsequent detailed description and examples with references made to the accompanying drawings, wherein:

FIG. 1 is a schematic diagram of an electronic device, according to an embodiment of the present disclosure.

FIG. 2 is a schematic diagram illustrating leakage current paths of transistors in a driving circuit, according to an embodiment of the present disclosure.

FIG. 3A is a diagram showing relationships among a gate bias voltage VG, a current ID, and a voltage TG of a first signal TGG received by a transistor of a driving circuit in an electronic device, according to an embodiment of the present disclosure;

FIG. 3B is a waveform diagram of the first signal TGG received by the transistor of the driving circuit in the electronic device, according to an embodiment of the present disclosure;

FIG. 3C is a waveform diagram of signals received by the driving circuit in the electronic device, according to an embodiment of the present disclosure.

FIG. 4 is a schematic diagram of a driving circuit in an electronic device, according to another embodiment of the present disclosure.

FIG. 5 is a schematic diagram of a driving circuit in an electronic device, according to another embodiment of the present disclosure.

FIG. 6 is a schematic diagram of a transistor structure used in an electronic device, according to an embodiment of the present disclosure.

FIG. 7 is a schematic diagram of a transistor structure used in an electronic device, according to another embodiment of the present disclosure.

FIG. 8 is a schematic diagram of a transistor structure used in an electronic device, according to another embodiment of the present disclosure.

FIG. 9 is a schematic diagram of a transistor structure used in an electronic device, according to another embodiment of the present disclosure.

FIG. 10A is a schematic diagram of an example of applying an electronic device to a display, according to an embodiment of the present disclosure;

FIG. 10B is a flowchart of operations when applying the electronic device to the display, according to an embodiment of the present disclosure.

FIG. 11A is a schematic diagram of an example of applying an electronic device to a display, according to another embodiment of the present disclosure;

FIG. 11B is a flowchart of operations when applying the electronic device to the display, according to another embodiment of the present disclosure.

FIG. 12A is a schematic diagram of an example of applying an electronic device to a reflective display, according to an embodiment of the present disclosure;

FIG. 12B is a flowchart of operations when applying the electronic device to the reflective display, according to an embodiment of the present disclosure.

### DETAILED DESCRIPTION OF THE INVENTION

The following description is made for the purpose of illustrating the general principles of the disclosure and should not be taken in a limiting sense. The scope of the disclosure is best determined by reference to the appended claims.

In order to make the objects, features, and advantages of the present disclosure more comprehensible, embodiments are described in detail below with reference to the accompanying drawings. To facilitate understanding for the reader and maintain the conciseness of the drawings, multiple drawings in the present disclosure may only depict a portion of an entire electronic device, and certain elements in the drawings are not drawn to scale.

The specification of the present disclosure provides different embodiments to illustrate the technical features of different implementations of the present disclosure. The arrangement, quantity, and size of each element in the embodiments are for illustrative purposes and are not intended to limit the present disclosure. In addition, repeated element numerals in the embodiments and drawings are for simplicity and clarity, and do not by themselves indicate a relationship between different embodiments.

Furthermore, the use of ordinal numbers such as “first” and “second” to modify elements in the claims does not by itself imply any prior ordinal number, nor does it represent the order of one claimed element relative to another, or the order of manufacturing steps. The use of such ordinal numbers is merely to distinguish one claimed element with a certain name from another claimed element with the same name.

In the present disclosure, features in various embodiments may be arbitrarily combined, substituted, or re-arranged, as long as such combinations do not contradict the spirit of the disclosure or result in logical conflicts.

In some embodiments of the present disclosure, the terms “coupled” and “electrically connected,” unless specifically defined otherwise, may encompass any direct or indirect electrical connection.

In the text, the terms “substantially” and “about” typically indicate a range within 10% of a given value, or within 5%, or 3%, or 2%, or 1%, or 0.5%. The quantities given herein are approximate, meaning that the terms “substantially” and “about” can be implied even if not explicitly stated.

The term “comprising” as mentioned throughout the specification and claims is an open-ended term and should be interpreted as “including, but not limited to.”

Furthermore, “connected” and “coupled” herein include any direct and indirect connection. Therefore, when an element or film layer is referred to as being “connected” to another element or film layer, it can be directly connected to the other element or film layer, or intervening elements or film layers may be present. When an element is referred to as being “directly connected” to another element or film layer, there are no intervening elements or film layers present. If a first device in a circuit is described as being coupled to a second device, it means that the first device can be directly electrically connected to the second device. When the first device is directly electrically connected to the second device, there are wires or passive components (such as resistors, capacitors, etc.) between the first device and the second device, and no other active electronic components are connected between them.

In an embodiment, the electronic device may include a display device, a backlight device, an antenna device, a sensing device, a tiled device, or a therapeutic/diagnostic device, but is not limited thereto. The electronic device may be a bendable or flexible electronic device. The display device may be a non-self-luminous display device or a self-luminous display device. The antenna device may be a liquid crystal type antenna device or a non-liquid crystal type antenna device. The sensing device may be a sensing device for sensing capacitance, light, heat, or ultrasonic waves, but is not limited thereto. Electronic components may include passive components and active components, such as capacitors, resistors, inductors, diodes, transistors, and the like. The diode may include a light-emitting diode or a photodiode. The light-emitting diode may include, for example, an organic light-emitting diode (OLED), a mini LED, a micro LED, or a quantum dot LED, but is not limited thereto. The tiled device may be, for example, a display tiled device or an antenna tiled device, but is not limited thereto. It should be noted that the electronic device may be any combination of the foregoing, but is not limited thereto. Hereinafter, a display device will be used as an electronic device to illustrate the content of the present disclosure, but the present disclosure is not limited thereto.

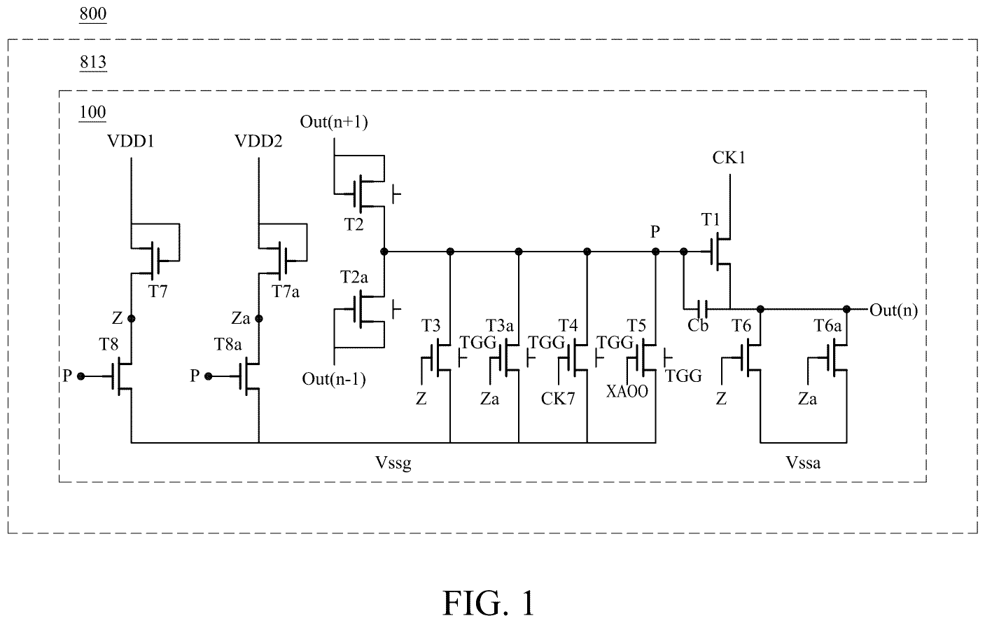

FIG. 1 is a schematic diagram of an electronic device according to an embodiment of the present disclosure.

Referring to FIG. 1, the electronic device 800 may include at least a peripheral region 813; and a driving circuit 100 disposed in the peripheral region 813.

As shown in FIG. 1, the driving circuit 100 includes: a first transistor T1, a second transistor T2, a transistor T2a, a third transistor T3, a transistor T3a, a fourth transistor T4, a fifth transistor T5, a sixth transistor T6, a transistor T6a, a seventh transistor T7, a transistor T7a, an eighth transistor T8, a transistor T8a, and a first capacitor Cb. In an embodiment, each of the first transistor T1 to the transistor T8a has a first terminal, a second terminal, and a control terminal.

In an embodiment, the first transistor T1 includes: a first terminal coupled to a clock signal CK1; a second terminal coupled to a first terminal of the sixth transistor T6, the first capacitor Cb, and an output terminal Out(n) of the driving circuit; and a control terminal coupled to a first node P, but not limited thereto.

In an embodiment, the second transistor T2 includes: a first terminal coupled to an output terminal Out(n+1) of a next-stage circuit and configured to receive a first voltage; a control terminal coupled to the first terminal and the output terminal Out(n+1) of the next-stage circuit and configured to receive the first voltage; and a second terminal coupled to the first node P and configured to charge the first node P, but not limited thereto. The transistor T2a includes: a first terminal coupled to the first node P; a second terminal coupled to an output terminal Out(n−1) of a previous-stage circuit and configured to output a second voltage; and a control terminal coupled to the second terminal and the output terminal Out(n−1) of the previous-stage circuit, but not limited thereto.

In an embodiment, the third transistor T3 includes: a first terminal coupled to the first node P; a control terminal connected to a node Z; and a second terminal coupled to ground Vssg, but not limited thereto. In an embodiment, the on/off state of the third transistor T3 can be controlled through the node Z. When the node Z is at a high potential, the third transistor T3 will be turned on, forming a conductive path between the first node P and the ground Vssg. Conversely, when the node Z is at a low potential, the third transistor T3 will be turned off, breaking the current path between the first node P and the ground Vssg, but not limited thereto.

In an embodiment, the transistor T3a includes: a first terminal coupled to the first node P; a control terminal connected to a node Za; and a second terminal coupled to the ground Vssg, but not limited thereto. In an embodiment, the node Za controls the on/off state of the transistor T3a. When the node Za is at a high potential, the transistor T3a will be turned on, forming a conductive path between the first node P and the ground Vssg. Conversely, when the node Za is at a low potential, the transistor T3a will be turned off, breaking the current path between the first node P and the ground Vssg, but not limited thereto.

In an embodiment, the fourth transistor T4 includes: a first terminal coupled to the first node P; a control terminal configured to receive a signal CK7; and a second terminal coupled to the ground Vssg, but not limited thereto. In an embodiment, the signal CK7 controls the on/off state of the fourth transistor T4. When the signal CK7 is at a high potential, the fourth transistor T4 will be turned on, forming a conductive path between the first node P and the ground Vssg. Conversely, when the signal CK7 is at a low potential, the fourth transistor T4 will be turned off, breaking the current path between the first node P and the ground Vssg, but not limited thereto.

In an embodiment, the fifth transistor T5 includes: a first terminal coupled to the first node P; a control terminal configured to receive a signal XA00; and a second terminal coupled to the ground Vssg, but not limited thereto. In an embodiment, the signal XA00 controls the on/off state of the fifth transistor T5. When the signal XA00 is at a high potential, the fifth transistor T5 will be turned on, forming a conductive path between the first node P and the ground Vssg. Conversely, when the signal XA00 is at a low potential, the fifth transistor T5 will be turned off, breaking the current path between the first node P and the ground Vssg, but not limited thereto.

In an embodiment, the sixth transistor T6 includes: a first terminal coupled to the second terminal of the first transistor T1 and the first capacitor Cb; a control terminal connected to the node Z; and a second terminal coupled to ground Vssa, but not limited thereto. In an embodiment, the node Z controls the on/off state of the sixth transistor T6. When the node Z is at a high potential, the sixth transistor T6 will be turned on, forming a conductive path between the second terminal of the first transistor T1 and the ground Vssa. Conversely, when the node Z is at a low potential, the sixth transistor T6 will be turned off, breaking the current path between the second terminal of the first transistor T1 and the ground Vssg, but not limited thereto.

The transistor Toa includes: a first terminal coupled to the second terminal of the first transistor T1 and the first capacitor Cb, wherein the first capacitor Cb is, for example, a parasitic capacitance, but not limited thereto; a control terminal connected to the node Za; and a second terminal coupled to the ground Vssa, but not limited thereto. In an embodiment, the node Za controls the on/off state of the transistor Toa. When the node Za is at a high potential, the transistor Toa will be turned on, forming a conductive path between the second terminal of the first transistor T1 and the ground Vssa. Conversely, when the node Za is at a low potential, the transistor T6a will be turned off, breaking the current path between the second terminal of the first transistor T1 and the ground Vssg, but not limited thereto.

In an embodiment, the seventh transistor T7 includes: a first terminal coupled to the control terminal and an operating voltage VDD1, such as a positive voltage, but not limited thereto; a control terminal coupled to the first terminal and the operating voltage VDD1; and a second terminal coupled to the eighth transistor T8 and connected to the node Z, but not limited thereto. The transistor T7a includes: a first terminal coupled to the control terminal and an operating voltage VDD2, such as a positive voltage, but not limited thereto; a control terminal coupled to the first terminal and the operating voltage VDD2; and a second terminal coupled to the transistor T8a and connected to the node Za, but not limited thereto.

In an embodiment, the eighth transistor T8 includes: a first terminal coupled to the second terminal of the seventh transistor T7; a control terminal coupled to the first node P; and a second terminal coupled to the ground Vssg, but not limited thereto. The transistor T8a includes: a first terminal coupled to the second terminal of the transistor T7a; a control terminal coupled to the first node P; and a second terminal coupled to the ground Vssg, but not limited thereto.

In an embodiment, the third transistor T3, the transistor T3a, the fourth transistor T4, and the fifth transistor T5 are each provided with a conductive layer for receiving a first signal TGG to adjust the threshold bias voltage of the third transistor T3, the transistor T3a, the fourth transistor T4, and the fifth transistor T5. The specific structure of the transistor provided with the conductive layer will be described later.

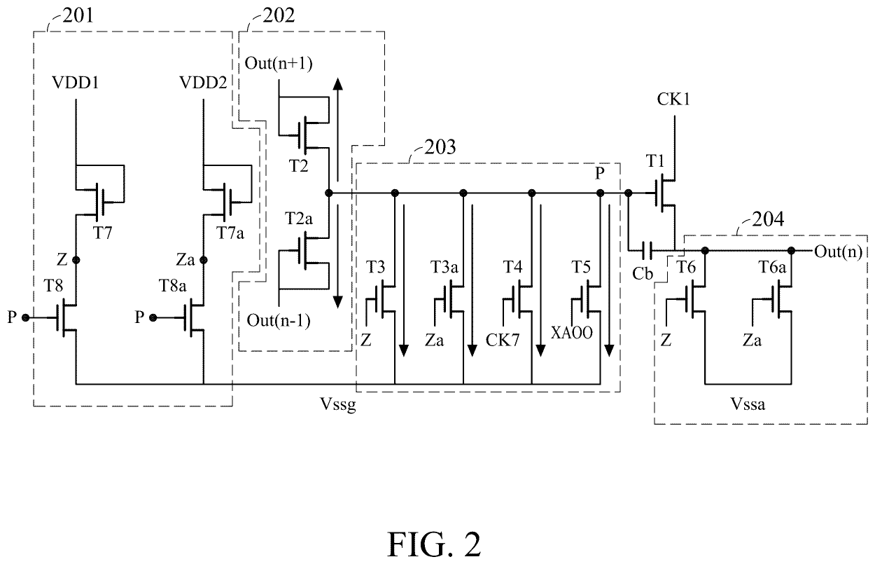

FIG. 2 is a schematic diagram illustrating leakage current paths in the transistors of the driving circuit 100, according to an embodiment of the present disclosure, due to threshold voltage VT shift.

In an embodiment, threshold voltage VT shifts may occur in the transistors due to variations in temperature or brightness. Such threshold voltage shifts may affect the performance of the transistors, generating leakage currents and thereby preventing the driving circuit 100 from operating as intended.

In an embodiment, when a threshold voltage VT shift occurs in a transistor, the likelihood of the threshold voltage VT shift can be reduced by applying a TGG signal to the conductive layer of the transistor, thereby ensuring the reliability of the driving circuit 100.

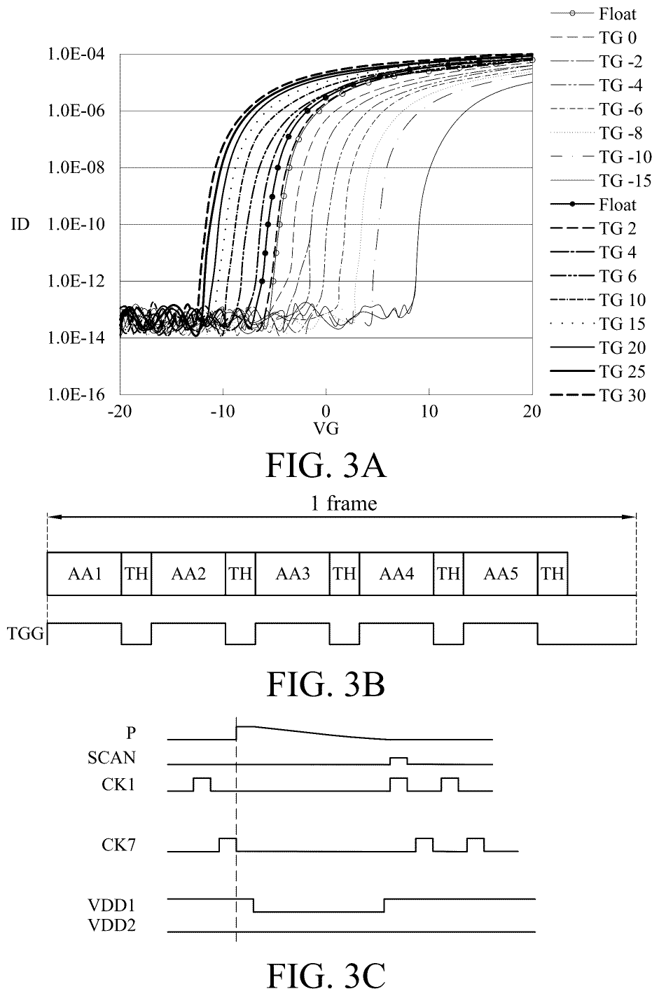

FIG. 3A is a diagram showing the relationships among a gate bias voltage VG, a current ID, and a voltage TG of a first signal TGG received by a transistor of a driving circuit in an electronic device, according to an embodiment of the present disclosure.

In an embodiment, when a transistor is detected to be at a high temperature (e.g., 85 degrees Celsius, but not limited thereto), the threshold voltage VT decreases, which can be regarded as a leftward shift of the characteristic curve of the transistor. This may cause poor transfer when used as a gate-on-panel (GOP) circuit, for example, due to leakage current causing leakage at the first node P, which in turn prevents other transistors from turning off as expected. At this time, a first signal TGG having a negative voltage TG can be applied to the conductive layer of the transistor to reduce the likelihood of threshold voltage VT shift, thereby ensuring the reliability of the driving circuit 100 and preventing it from being affected by the threshold voltage VT shift.

In an embodiment, when a transistor is detected to be at a low temperature (e.g., −40 degrees Celsius, but not limited thereto), the threshold voltage VT increases, which can be regarded as a rightward shift of the characteristic curve of the transistor. This may cause poor transfer when used as a GOP circuit, for example, insufficient driving force of the first transistor T1, the second transistor T2, and the transistor T2a. At this time, a first signal TGG having a positive voltage TG can be applied to the conductive layer of the transistor to reduce the likelihood of threshold voltage VT shift, thereby ensuring the reliability of the driving circuit 100.

Thus, the present disclosure can utilize the application of the first signal TGG to the conductive layer of the transistor to simultaneously satisfy the gate operation of the circuit in high and low temperature ranges, achieving the effect of stabilizing circuit operation without being affected by temperature.

FIG. 3B is a waveform diagram of the first signal TGG received by the driving circuit in the electronic device, according to an embodiment of the present disclosure.

In an embodiment, the electronic device is a display. During the display of one frame by the display, it can be divided into the following periods: an active period AA1, an inactive period TH (also called Touch hole), an active period AA2, an inactive period TH, an active period AA3, an inactive period TH, an active period AA4, an inactive period TH, an active period AA5, and an inactive period TH.

In an embodiment, during the active period AA1, the active period AA2, the active period AA3, the active period AA4, and the active period AA5, the first signal TGG is at a high potential, for example, a positive voltage of 15V; during the inactive period TH, the first signal TGG is at a low potential, for example, a negative voltage of −15V, but not limited thereto. For example, the high potential can be any positive voltage, and the low potential can be ground; or, for example, the high potential can be ground, and the low potential can be any negative voltage.

FIG. 3C is a waveform diagram of signals received by the driving circuit in the electronic device, according to an embodiment of the present disclosure.

FIG. 3C shows that when the voltage at the first node P decreases due to leakage current, and even falls below the threshold value of the gate bias voltage of the first transistor T1, the first transistor T1 may not be turned off as expected, which in turn may cause the circuit to not operate as expected. For example, if the driving circuit 100 is used in a display, it may cause abnormalities in the displayed image of the display, such as display non-uniformity.

Therefore, in the embodiment of the present disclosure, by applying the first signal TGG to the conductive layer of the transistor, the characteristic curve of the transistor is shifted to reduce the likelihood of threshold voltage VT shift of the transistor caused by variations in temperature/brightness, thereby ensuring the reliability of the overall circuit.

In an embodiment, when the transistor is exposed to high-brightness illumination, the threshold voltage VT decreases, which can be regarded as a leftward shift of the characteristic curve of the transistor. This may cause poor transfer when used as a gate-on-panel (GOP) circuit, for example, due to leakage current causing leakage at the first node P, which in turn prevents other transistors from turning off as expected. At this time, a first signal TGG having a negative voltage TG can be applied to the conductive layer of the transistor to reduce the likelihood of threshold voltage VT shift, thereby ensuring the reliability of the driving circuit 100.

In an embodiment, when the transistor is exposed to low-brightness illumination, the threshold voltage VT increases, which can be regarded as a rightward shift of the characteristic curve of the transistor. This may cause poor transfer when used as a GOP circuit, for example, insufficient driving force of the first transistor T1, the second transistor T2, and the transistor T2a. At this time, a first signal TGG having a positive voltage TG can be applied to the conductive layer of the transistor to reduce the likelihood of threshold voltage VT shift, thereby ensuring the reliability of the driving circuit 100.

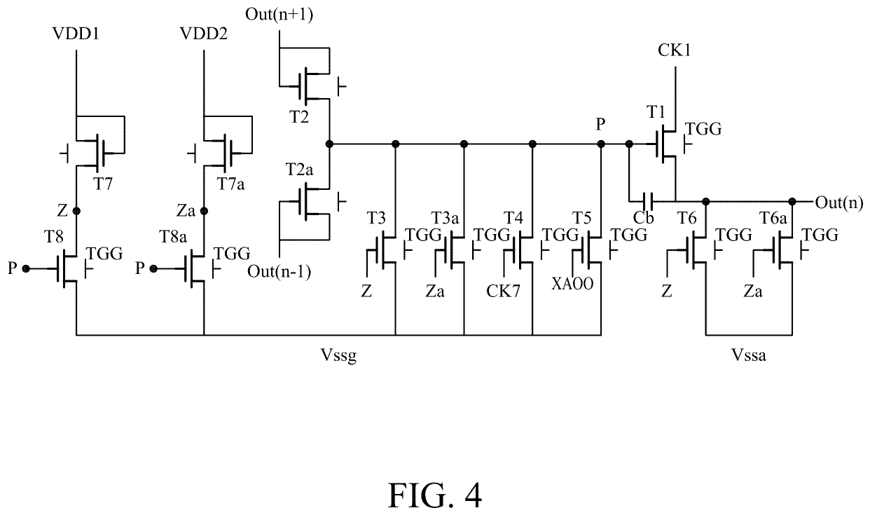

FIG. 4 is a schematic diagram of a driving circuit in an electronic device, according to another embodiment of the present disclosure.

In this embodiment, the first transistor T1, the third transistor T3, the transistor T3a, the fourth transistor T4, the fifth transistor T5, the sixth transistor T6, the transistor T6a, the eighth transistor T8, and the transistor T8a are provided with a conductive layer for receiving the first signal TGG.

Using such a configuration, since other transistors in the circuit are also provided with a conductive layer for receiving the first signal TGG, the likelihood of threshold voltage VT curve shift of the transistors caused by variations in temperature/brightness can be more effectively reduced, thereby ensuring the reliability of the overall circuit.

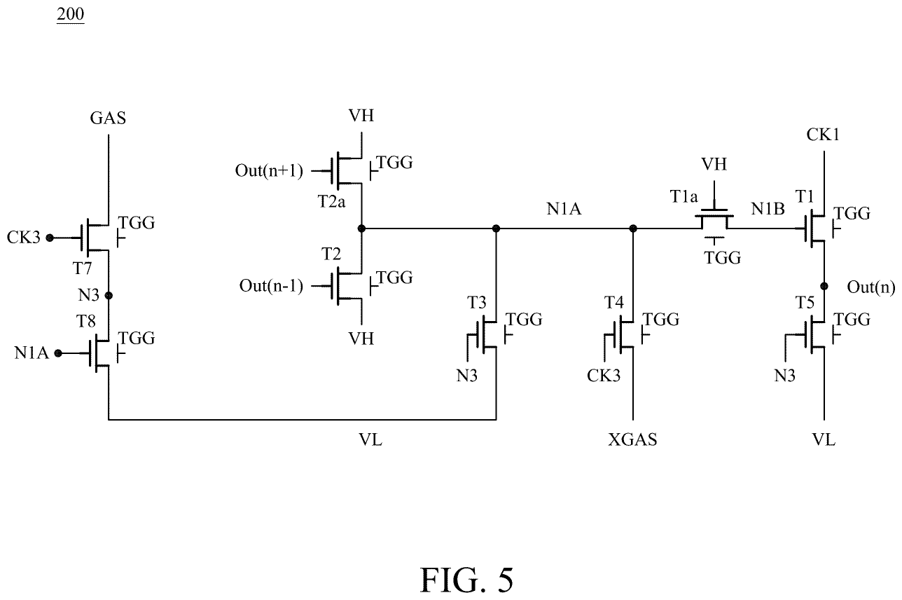

FIG. 5 is a schematic diagram of a driving circuit 200 in an electronic device, according to another embodiment of the present disclosure.

Referring to FIG. 5, the driving circuit 200 of this embodiment includes: a first transistor T1, a transistor T1a, a second transistor T2, a transistor T2a, a third transistor T3, a fourth transistor T4, a fifth transistor T5, a seventh transistor T7, and an eighth transistor T8, each transistor having a first terminal, a second terminal, and a control terminal.

In an embodiment, the first transistor T1 includes: a first terminal coupled to a clock signal CK1; a second terminal coupled to a first terminal of the fifth transistor T5; and a control terminal coupled to a second terminal of the transistor T1a, but not limited thereto. The transistor T1a includes: a first terminal coupled to a second node NIA; a control terminal configured to receive a high potential VH; and a second terminal coupled to the control terminal of the first transistor T1, but not limited thereto.

In an embodiment, the second transistor T2 includes: a first terminal configured to receive a high potential VH; a second terminal coupled to the second node NIA; and a control terminal coupled to an output terminal Out(n−1) of a previous-stage circuit, but not limited thereto. The transistor T2a includes: a first terminal coupled to the second node NIA; a second terminal connected to a low potential VL; and a control terminal coupled to an output terminal Out(n+1) of a next-stage circuit, but not limited thereto.

In an embodiment, the third transistor T3 includes: a first terminal coupled to the second node NA; a second terminal connected to the low potential VL; and a control terminal connected to a node N3, but not limited thereto.

In an embodiment, the fourth transistor T4 includes: a first terminal coupled to the second node NIA; a second terminal connected to a node XGAS; and a control terminal configured to receive a signal CK3, but not limited thereto. In an embodiment, the node XGAS is ground, but may also be another specific node.

In an embodiment, the fifth transistor T5 includes: a first terminal coupled to the second terminal of the first transistor T1 and an output terminal Out(n); a second terminal connected to the low potential VL; and a control terminal connected to the node N3, but not limited thereto.

In an embodiment, the seventh transistor T7 includes: a first terminal connected to a node GAS; a control terminal configured to receive the signal CK3; and a second terminal coupled to a first terminal of the eighth transistor T8 and the node N3, but not limited thereto. In an embodiment, the node GAS is ground, but may also be another specific node.

In an embodiment, the eighth transistor T8 includes: a first terminal coupled to the second terminal of the seventh transistor T7 and the node N3; a control terminal coupled to the second node NIA; and a second terminal connected to the low potential VL, but not limited thereto.

In this embodiment, the first transistor T1, the transistor T1a, the second transistor T2, the transistor T2a, the third transistor T3, the fourth transistor T4, the fifth transistor T5, the seventh transistor T7, and the eighth transistor T8 are provided with a conductive layer for receiving the first signal TGG, but not limited thereto.

Using such a configuration, since the transistors are provided with a conductive layer for receiving the first signal TGG, the likelihood of threshold voltage VT shift of the transistors caused by variations in temperature/brightness can be more effectively reduced, thereby ensuring the reliability of the overall circuit. That is, even with different circuit configurations, by providing the transistors with a conductive layer and having the conductive layer receive the first signal TGG, the effect of effectively reducing the likelihood of threshold voltage VT shift of the transistors caused by variations in temperature/brightness can be achieved.

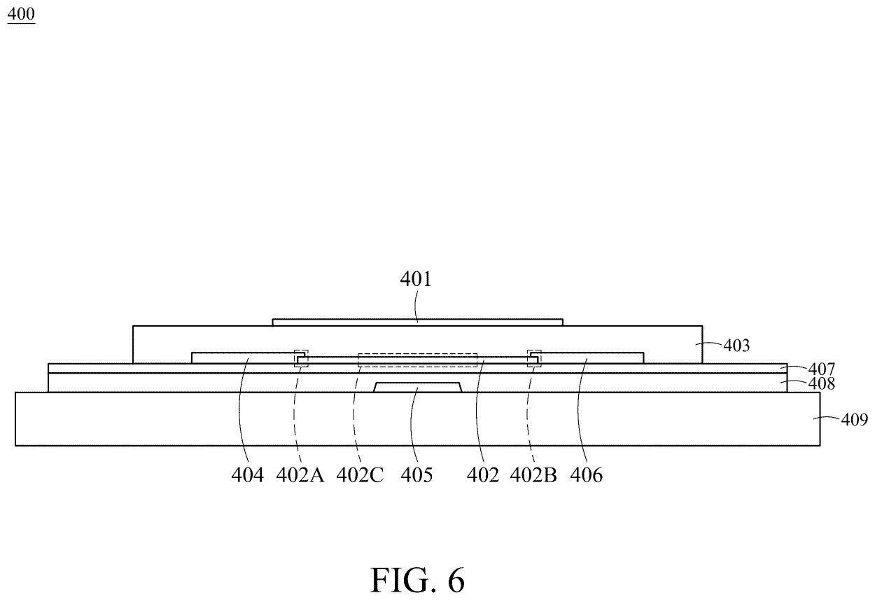

FIG. 6 is a schematic diagram of a transistor structure 400 used in an electronic device, according to an embodiment of the present disclosure.

Referring to FIG. 6, the transistor structure 400 includes a conductive layer 401, a semiconductor layer 402, a dielectric layer 403, a source 404, a gate 405, a drain 406, a first buffer layer 407, a second buffer layer 408, and a substrate 409.

In an embodiment, the conductive layer 401 overlaps the gate 405 in the normal direction of the electronic device. More specifically, in the normal direction of the electronic device, the following are sequentially stacked: the conductive layer 401, the dielectric layer 403, the semiconductor layer 402, the first buffer layer 407, the second buffer layer 408, the gate 405, and the substrate 409.

In an embodiment, the conductive layer 401 may include indium tin oxide (ITO) or a metal material (molybdenum, titanium, or copper), etc., and is not limited thereto, and may also include other suitable materials or combinations of the aforementioned materials.

In an embodiment, when the conductive layer 401 receives the input of the first signal TGG, the threshold voltage VT curve of the transistor structure 400 can be shifted, thereby ensuring the reliability of the transistor structure 400 in environments with different temperatures/brightness levels.

In an embodiment, the semiconductor layer 402 may include amorphous indium gallium zinc oxide (a-IGZO), amorphous silicon (a-Si), polycrystalline silicon (p-Si), low-temperature polycrystalline silicon (LTPS), and other semiconductor materials, and is not limited thereto, and may also include other suitable materials or combinations of the aforementioned materials.

In an embodiment, the dielectric layer 403, the first buffer layer 407, and the second buffer layer 408 may include silicon nitride (SiNx), silicon oxide (SiOx), a polymer, etc., and are not limited thereto, and may also include other suitable materials or combinations of the aforementioned materials.

In an embodiment, the dielectric layer 403 is disposed between the conductive layer 401 and the semiconductor layer 402, but not limited thereto.

In an embodiment, the gate 405, the source 404, and the drain 406 may include ITO or a metal material (molybdenum, titanium, or copper), etc., and are not limited thereto, and may also include other suitable materials or combinations of the aforementioned materials.

In an embodiment, the source 404 has a portion disposed on a first portion 402A of the semiconductor layer 402, and the source 404 is in contact with the first portion 402A of the semiconductor layer 402.

In an embodiment, the drain 406 has a portion disposed on a second portion 402B of the semiconductor layer 402, and the drain 406 is in contact with the second portion 402B of the semiconductor layer 402.

In an embodiment, the gate 405 is disposed on a third portion 402C of the semiconductor layer 402. In the normal direction of the transistor structure, the gate 405 overlaps the third portion 402C of the semiconductor layer, and the third portion 402C is located between the first portion 402A and the second portion 402B.

In an embodiment, the conductive layer 401 is disposed on the dielectric layer 403, but not limited thereto. The first buffer layer 407 and the second buffer layer 408 are sequentially disposed between the gate 405 and the semiconductor layer 402. The thickness of the first buffer layer 407 is less than the thickness of the second buffer layer 408. Furthermore, in some embodiments, the material of the first buffer layer 407 contains a higher proportion of oxygen than the material of the second buffer layer 408, and the material of the second buffer layer 408 contains a higher proportion of nitrogen than the material of the first buffer layer 407, but not limited thereto.

In an embodiment, the substrate 409 may include glass, quartz, sapphire, ceramic, polycarbonate (PC), polyimide (PI), polyethylene terephthalate (PET), other suitable materials, or combinations of the foregoing, but is not limited thereto.

Using such a configuration, the likelihood of threshold voltage VT shift caused by variations in temperature/brightness can be more effectively reduced, thereby ensuring the reliability of the overall circuit.

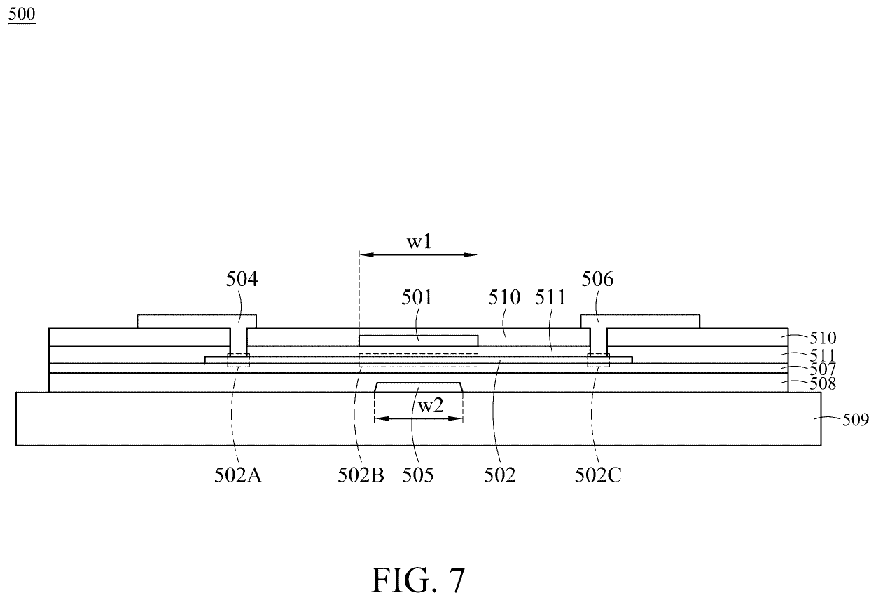

FIG. 7 is a schematic diagram of a transistor structure 500 used in an electronic device, according to another embodiment of the present disclosure.

Referring to FIG. 7, the transistor structure 500 includes: a gate 501, a semiconductor layer 502, a source 504, a conductive layer 505, a drain 506, a first buffer layer 507, a second buffer layer 508, a substrate 509, a dielectric layer 511, and a dielectric layer 510.

In an embodiment, the gate 501 and the conductive layer 505 overlap in the normal direction of the transistor structure 500 included in the electronic device. More specifically, in the normal direction, the dielectric layer 510, the gate 501, the dielectric layer 511, the semiconductor layer 502, the first buffer layer 507, the second buffer layer 508, the conductive layer 505, and the substrate 509 are sequentially stacked. In an embodiment, the source 504 and the drain 506 penetrate through the dielectric layer 511 and the dielectric layer 510 to be in contact and electrically connected, but not limited thereto. In an embodiment, in a cross-sectional direction of the electronic device, a width w1 of the gate 501 is greater than a width w2 of the conductive layer 505, but not limited thereto.

In an embodiment, when the conductive layer 505 receives the input of the first signal TGG, the threshold voltage VT curve of the transistor structure 500 can be shifted, thereby ensuring the reliability of the transistor structure 500 in environments with different temperatures/brightness levels.

In an embodiment, the dielectric layer 511 may be a Transparent Gate Insulator (TGI) layer, and the dielectric layer 510 may be an Inter-Layer Dielectric (ILD) layer, but not limited thereto. In an embodiment, the dielectric layers 510, 511 may comprise an organic material or an inorganic material. The material of the dielectric layers 510, 511 may be, for example, silicon nitride (SiNx), aluminum oxide (Al2O3), or other materials with a high dielectric constant (High-k), and is not limited thereto, and may also include other suitable materials or combinations of the aforementioned materials. In an embodiment, the dielectric layer 511 may be disposed between the gate 501 and the semiconductor layer 502, and is not limited thereto.

In an embodiment, the dielectric layer 510 is located on the gate 501 and may include both sides covering the gate 501, but not limited thereto.

Using such a configuration, since the transistor structure 500 is provided with the conductive layer 505 for receiving the first signal TGG, when the transistor structure 500 is used as a transistor, the likelihood of threshold voltage VT shift caused by variations in temperature/brightness can be more effectively reduced, thereby ensuring the reliability of the overall circuit.

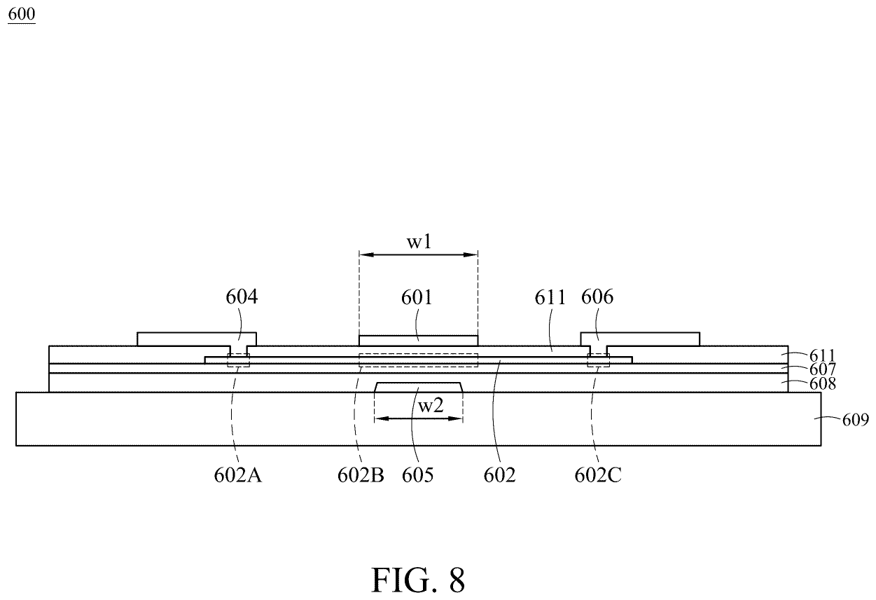

FIG. 8 is a schematic diagram of a transistor structure 600 used in an electronic device, according to another embodiment of the present disclosure.

Referring to FIG. 8, the transistor structure 600 includes: a gate 601, a semiconductor layer 602, a source 604, a conductive layer 605, a drain 606, a first buffer layer 607, a second buffer layer 608, a substrate 609, and a dielectric layer 611.

In an embodiment, the gate 601 and the conductive layer 605 overlap in the normal direction of the electronic device. More specifically, in the normal direction, the gate 601, the dielectric layer 611, the semiconductor layer 602, the first buffer layer 607, the second buffer layer 608, the conductive layer 605, and the substrate 609 are sequentially stacked.

In an embodiment, when the conductive layer 605 receives the input of the first signal TGG, the threshold voltage VT curve of the transistor structure 600 can be shifted, thereby ensuring the reliability of the transistor structure 600 in environments with different temperatures/brightness levels.

In an embodiment, the gate 601, the source 604, and the drain 606 are located on the dielectric layer 611, and are not limited thereto. In an embodiment, the gate 601, the source 604, and the drain 606 may be fabricated in the same process. In other words, the gate 601, a portion of the source 604, and a portion of the drain 606 may contact the dielectric layer 611. The source 604 and the drain 606 penetrate through the dielectric layer 611 to be in contact and electrically connected, but not limited thereto. In an embodiment, in a cross-sectional direction of the electronic device, the width w1 of the gate 601 is greater than the width w2 of the conductive layer 605, but not limited thereto.

Using such a configuration, since the transistor structure 600 is provided with the conductive layer 605 for receiving the first signal TGG, when the transistor structure 600 is used as a transistor, the likelihood of threshold voltage VT shift caused by variations in temperature/brightness can be more effectively reduced, thereby ensuring the reliability of the overall circuit.

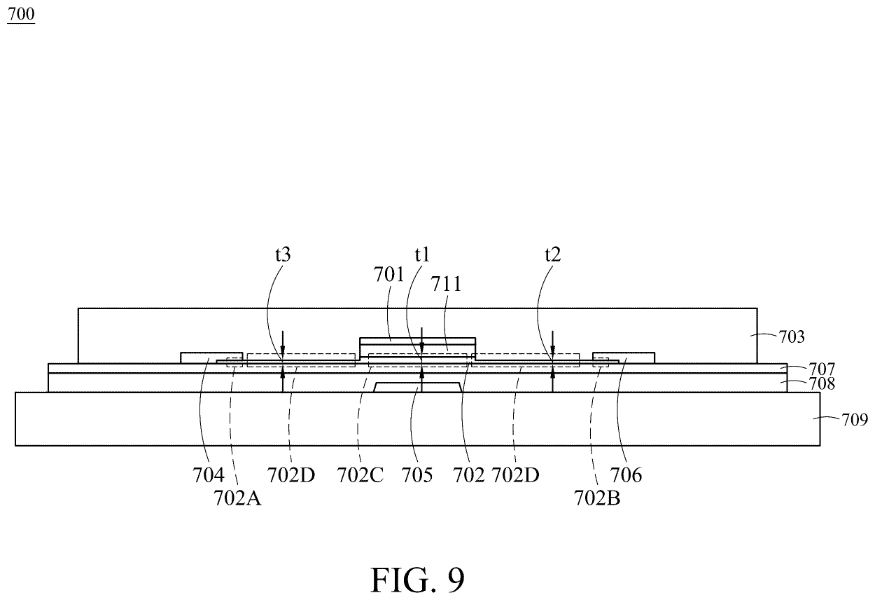

FIG. 9 is a schematic diagram of a transistor structure 700 used in an electronic device, according to another embodiment of the present disclosure.

Referring to FIG. 9, the transistor structure 700 includes: a gate 701, a semiconductor layer 702, a dielectric layer 703, a source 704, a conductive layer 705, a drain 706, a first buffer layer 707, a second buffer layer 708, a substrate 709, and a dielectric layer 711.

In an embodiment, the gate 701 and the conductive layer 705 overlap in the normal direction of the electronic device. More specifically, in the normal direction, the dielectric layer 703, the gate 701, the dielectric layer 711, the semiconductor layer 702, the first buffer layer 707, the second buffer layer 708, the conductive layer 705, and the substrate 709 are sequentially stacked.

In an embodiment, the dielectric layer 703 is disposed on the gate 701, the source 704, and the drain 706. Furthermore, the source 704 has a portion disposed on a first portion 702A of the semiconductor layer 702, and the source 704 is in contact with the first portion 702A of the semiconductor layer 702. The drain 706 has a portion disposed on a second portion 702B of the semiconductor layer 702, and the drain 706 is in contact with the second portion 702B of the semiconductor layer 702. The gate 701 is disposed on a third portion 702C of the semiconductor layer 702. In the normal direction of the transistor structure, the gate 701 overlaps the third portion 702C of the semiconductor layer, and the third portion 702C is located between the first portion 702A and the second portion 702B. A thickness t1 of the third portion 702C is greater than a thickness t2 of the first portion 702A and/or a thickness t3 of the second portion 702B, but not limited thereto.

In an embodiment, an impedance of the third portions 402C, 502C, 602C, 702C of the semiconductor layers 402, 502, 602, 702 is lower than an impedance of the first portions 402A, 502A, 602A, 702A and the second portions 402B, 502B, 602B, 702B of the semiconductor layers 402, 502, 602, 702, but not limited thereto. In some embodiments, taking FIG. 9 as an example, a fourth portion 702D of the semiconductor layer 702 is disposed between the first portion 702A (or the second portion 702B) and the third portion 702C, and an impedance of the fourth portion 702D of the semiconductor layer 702 is greater than the impedance of the first portions 402A, 502A, 602A, 702A and the second portions 402B, 502B, 602B, 702B of the semiconductor layers 402, 502, 602, 702, but not limited thereto.

In an embodiment, when the conductive layer 705 receives the input of the first signal TGG, the threshold voltage VT curve of the transistor structure 700 can be shifted, thereby ensuring the reliability of the transistor structure 700 in environments with different temperatures/brightness levels.

Using such a configuration, since the transistor structure 700 is provided with the conductive layer 705 for receiving the first signal TGG, when the transistor structure 700 is used as a transistor, the likelihood of threshold voltage VT shift caused by variations in temperature/brightness can be more effectively reduced, thereby ensuring the reliability of the overall circuit.

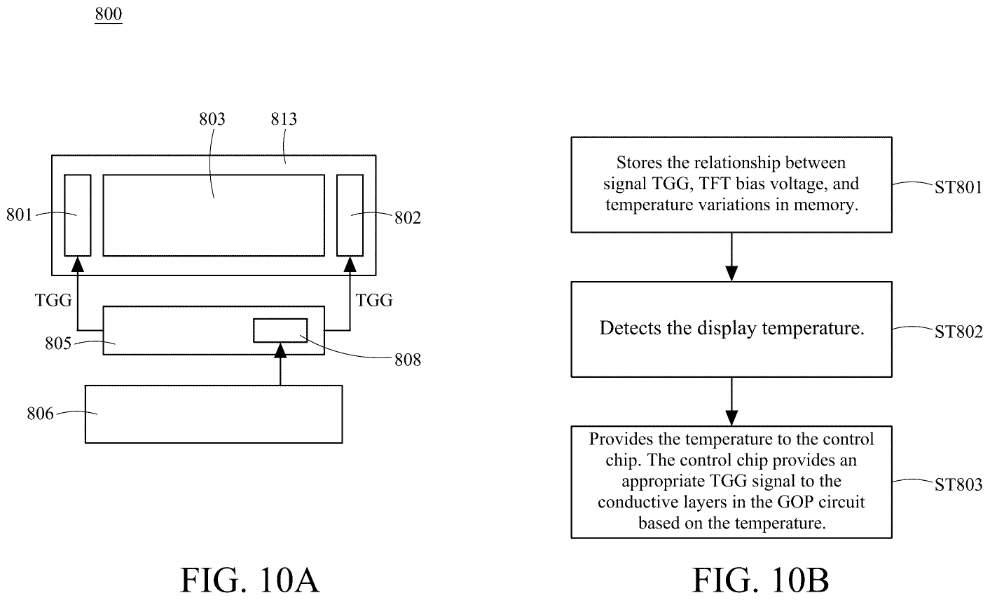

FIG. 10A is a schematic diagram of an example of applying an electronic device 800 to a display, according to an embodiment of the present disclosure.

Referring to FIG. 10A, the electronic device (display) 800 includes: gate-on-panel (GOP) circuits 801, 802, an active area 803, a control chip 805, and a temperature sensor 806. In some embodiments, the GOP circuits 801, 802 can be regarded as an example of applying any of the driving circuits 100, 200 to a display.

In an embodiment, transistors in the GOP circuits 801, 802 have conductive layers that receive a first signal TGG from the control chip 805 according to different temperatures, to adjust the threshold bias voltage of these transistors.

In an embodiment, the active area 803 is, for example, a liquid crystal active area, which receives driving signals from the GOP circuits 801, 802 to display images. Although the GOP circuits 801, 802 are respectively disposed on two sides of the peripheral region 813 of the active area 803, it is not limited thereto. For example, only one of the GOP circuits 801, 802 may be disposed on one side.

In an embodiment, the control chip 805 is, for example, a touch and display driver integration (TDDI) chip, which includes a memory 808 that stores the relationship between the first signal TGG, the TFT bias voltage, and the temperature variation, so that the control chip 805 can output an appropriate first signal TGG to the GOP circuits 801, 802 according to different temperatures.

In an embodiment, the temperature sensor 806 is, for example, a thermistor, but not limited thereto. In an embodiment, the temperature sensor 806 detects the display temperature, but not limited thereto; the temperature sensor 806 may also detect the temperature of the GOP circuits 801, 802. The temperature sensor 806 provides the detected temperature to the control chip 805, and the control chip 805 provides an appropriate first signal TGG to the conductive layers in the GOP circuits 801, 802 according to the temperature. In some embodiments, the temperature sensor 806 is disposed on a printed circuit board, but not limited thereto.

FIG. 10B is a flowchart of operations when applying the electronic device 800 to the display, according to an embodiment of the present disclosure.

In an embodiment, in step ST801, the relationship between the first signal TGG, the TFT bias voltage, and the temperature variation is stored in the memory 808 of the control chip 805, but not limited thereto. In some embodiments, the relationship between the first signal TGG, the TFT bias voltage, and the temperature variation may be presented in the form of a look-up table, but not limited thereto.

In an embodiment, in step ST802, the temperature sensor 806 detects the display temperature, but not limited thereto. In some embodiments, the temperature sensor 806 may also detect the temperature of the GOP circuits 801, 802.

In an embodiment, in step ST803, the temperature sensor 806 provides the detected temperature to the control chip 805, and the control chip 805 provides an appropriate first signal TGG to the conductive layers in the GOP circuits 801, 802 according to the temperature.

Using such a configuration, in the electronic device (display) 800, since the transistors of the GOP circuits 801, 802 are provided with conductive layers for receiving the first signal TGG, and the control chip 805 provides an appropriate first signal TGG according to the temperature, when the electronic device (display) 800 is in use, the likelihood of threshold voltage shift of the transistors in the GOP circuits 801, 802 due to temperature variations can be more effectively reduced, thereby ensuring the reliability of the electronic device (display) 800.

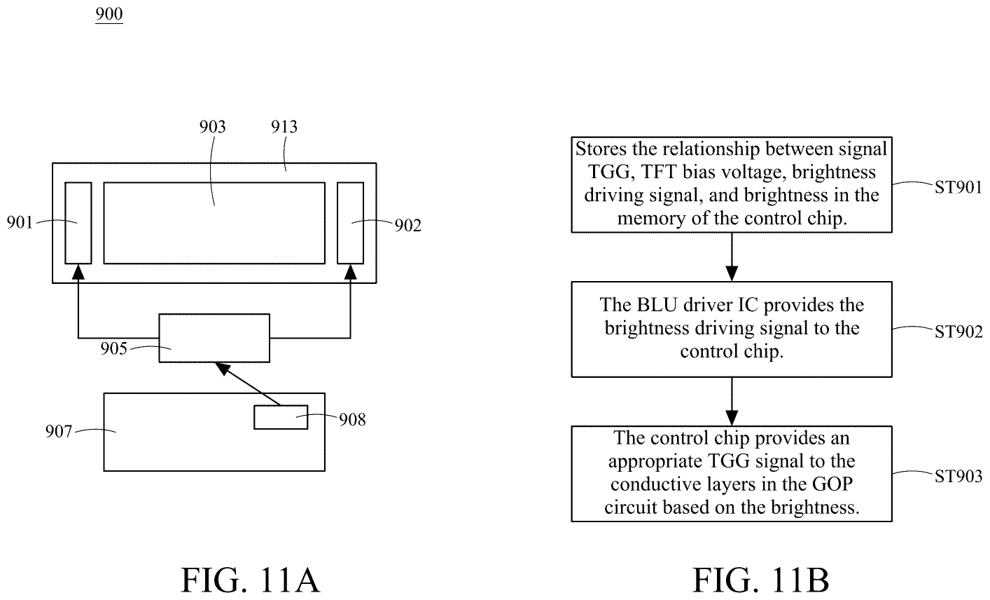

FIG. 11A is a schematic diagram of an example of applying an electronic device 900 to a display, according to another embodiment of the present disclosure.

Compared with the previous embodiment, which determines the first signal TGG according to the temperature, this embodiment determines the first signal TGG according to the brightness. This is because the threshold voltage shift of the transistor may also be caused by the influence of brightness. Therefore, this embodiment determines the first signal TGG according to the brightness, which can more effectively reduce the likelihood of threshold voltage shift of the transistors in the GOP circuits 901, 902 due to variations in brightness, thereby ensuring the reliability of the electronic device (display) 900.

Referring to FIG. 11A, the electronic device (display) 900 includes: GOP circuits 901, 902, an active area 903, a control chip 905, and a backlight unit (BLU) 907.

In an embodiment, the transistors in the GOP circuits 901, 902 have conductive layers that receive the first signal TGG from the control chip 905 according to the different brightness levels to adjust the threshold bias voltage of these transistors.

In an embodiment, the active area 903 is, for example, a liquid crystal active area, which receives driving signals from the GOP circuits 901, 902 to display images. Although the GOP circuits 901, 902 are respectively disposed on two sides of the peripheral region 913 of the active area 903, it is not limited thereto. For example, only one of the GOP circuits 901, 902 may be disposed on one side.

In an embodiment, the control chip 905 receives a brightness driving signal representative of the brightness and provides a first signal TGG according to the different brightness levels.

In an embodiment, the control chip 905 includes a memory that stores the relationship between the first signal TGG, the TFT bias voltage, and the brightness, so that the control chip 905 can output an appropriate first signal TGG to the GOP circuits 901, 902 according to the different brightness levels. In an embodiment, the relationship between the first signal TGG, the TFT bias voltage, and the brightness stored in the memory is as follows: when the brightness is higher, the threshold voltage VT of the transistor may decrease, which can be regarded as a leftward shift of the characteristic curve of the transistor. Therefore, the first signal TGG with a negative voltage TG should be applied to reduce the likelihood of threshold voltage VT shift, thereby ensuring the reliability of the electronic device (display) 900 and reducing problems such as diffusion and direct reflection on the electronic device (display) 900; when the brightness is lower, the threshold voltage VT of the transistor may increase, which can be regarded as a rightward shift of the characteristic curve of the transistor. Therefore, the first signal TGG with a positive voltage TG should be applied to reduce the likelihood of threshold voltage VT shift, thereby ensuring the reliability of the electronic device (display) 900.

In an embodiment, the backlight unit (BLU) 907 is, for example, a light-emitting diode unit that provides backlight to the active area 903, but not limited thereto. In an embodiment, the backlight unit 907 includes a BLU driver IC 908.

In an embodiment, the BLU driver IC 908 provides a backlight driving signal to the BLU 907. When the driving voltage or driving current of the backlight driving signal is larger, the brightness of the backlight provided by the BLU 907 to the active area 903 is greater; when the driving voltage or driving current of the backlight driving signal is smaller, the brightness of the backlight provided by the BLU 907 to the active area 903 is smaller. In addition, the BLU driver IC 908 also provides the backlight driving signal to the control chip 905. The control chip 905 outputs an appropriate first signal TGG to the conductive layers of the transistors in the GOP circuits 901, 902 according to the brightness represented by the received backlight driving signal.

FIG. 11B is a flowchart of operations when applying the electronic device to the display, according to another embodiment of the present disclosure.

In an embodiment, in step ST901, the relationship between the first signal TGG, the TFT bias voltage, the brightness driving signal, and the brightness is stored in the memory of the control chip 905, but not limited thereto.

In an embodiment, in step ST902, the BLU driver IC provides the brightness driving signal to the control chip 905.

In an embodiment, in step ST903, the control chip 905 provides an appropriate TGG signal to the conductive layers in the GOP circuits 901, 902 according to the brightness represented by the received brightness driving signal, and according to the relationship between the first signal TGG, the TFT bias, the brightness driving signal and the brightness stored in the memory.

Using such a configuration, in the electronic device (display) 900, since the transistors of the GOP circuits 901, 902 are provided with conductive layers for receiving the first signal TGG, and the control chip 905 provides an appropriate first signal TGG according to the brightness, when the electronic device (display) 900 is in use, the likelihood of threshold voltage shift of the transistors in the GOP circuits 901, 902 due to variations in brightness can be more effectively reduced, thereby ensuring the reliability of the electronic device (display) 900.

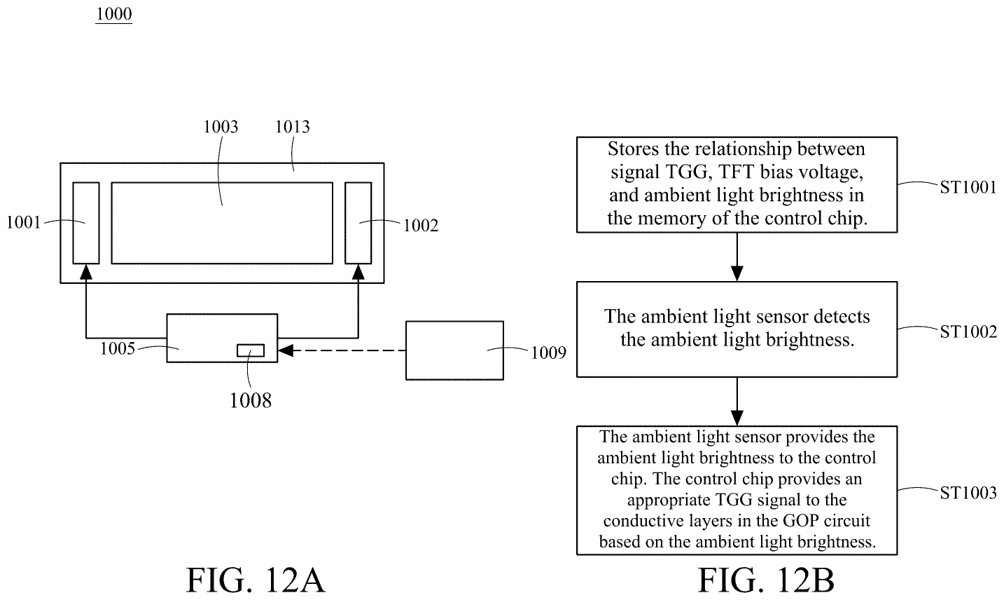

FIG. 12A is a schematic diagram of an example of applying an electronic device 1000 to a reflective display, according to an embodiment of the present disclosure.

Compared with the previous embodiment, which determines the first signal TGG according to the brightness represented by the backlight driving signal, this embodiment determines the first signal TGG according to the ambient light brightness detected by an ambient light sensor 1009. Because the threshold voltage shift of the transistor may also be caused by the influence of the ambient light brightness surrounding the electronic device (display) 1000, this embodiment can more effectively reduce the likelihood of threshold voltage shift of the transistors in the GOP circuits 1001, 1002 caused by variations in brightness by determining the first signal TGG according to the ambient light brightness, thereby ensuring the reliability of the electronic device (display) 1000.

Referring to FIG. 12A, the electronic device (display) 1000 includes: GOP circuits 1001, 1002, an active area 1003, a control chip 1005, and an ambient light sensor 1009. In an embodiment, the electronic device (display) 1000 is, for example, a reflective display, but not limited thereto.

In an embodiment, the transistors in the GOP circuits 1001, 1002 have conductive layers that receive the first signal TGG from the control chip 1005 according to different ambient light brightness levels to adjust the threshold bias voltage of these transistors.

In an embodiment, the active area 1003 is, for example, a liquid crystal active area, which receives driving signals from the GOP circuits 1001, 1002 to display images. Although the GOP circuits 1001, 1002 are respectively disposed on two sides of the peripheral region 1013 of the active area 1003, it is not limited thereto. For example, only one of the GOP circuits 1001, 1002 may be disposed on one side.

In an embodiment, the control chip 1005 includes a memory 1008 that stores the relationship between the first signal TGG, the TFT bias voltage, and the ambient light brightness, so that the control chip 1005 can output an appropriate first signal TGG to the GOP circuits 1001, 1002 according to different ambient light brightness levels.

In an embodiment, the memory 1008 stores the relationship between the first signal TGG, the TFT bias voltage, and the ambient light brightness. In an embodiment, the relationship between the first signal TGG, the TFT bias voltage, and the ambient light brightness stored in the memory 1008 is as follows: when the ambient light brightness is higher, the threshold voltage VT of the transistor may decrease, which can be regarded as a leftward shift of the characteristic curve of the transistor. Therefore, the first signal TGG with a negative voltage TG should be applied to reduce the likelihood of threshold voltage VT shift, thereby ensuring the reliability of the electronic device (display) 1000 and reducing problems such as diffusion and direct reflection on the electronic device (display) 1000; when the ambient light brightness is lower, the threshold voltage VT of the transistor may increase, which can be regarded as a rightward shift of the characteristic curve of the transistor. Therefore, the first signal TGG with a positive voltage TG should be applied to reduce the likelihood of threshold voltage VT shift, thereby ensuring the reliability of the electronic device (display) 1000.

FIG. 12B is a flowchart of operations when applying the electronic device to the reflective display, according to another embodiment of the present disclosure.

In an embodiment, in step ST1001, the relationship between the first signal TGG, the TFT bias voltage, and the ambient light brightness is stored in the memory of the control chip 1005, but not limited thereto.

In an embodiment, in step ST1002, the ambient light sensor 1009 detects the ambient light brightness.

In an embodiment, in step ST1003, the ambient light sensor 1009 provides the detected ambient light brightness to the control chip 1005. The control chip 1005, based on the relationship between the first signal TGG, the TFT bias voltage, and the ambient light brightness stored in the memory, provides an appropriate TGG signal to the conductive layers in the GOP circuits 1001, 1002 according to the received ambient light brightness.

Using such a configuration, in the electronic device (display) 1000, since the transistors of the GOP circuits 1001, 1002 are provided with conductive layers for receiving the first signal TGG, and the control chip 1005 provides an appropriate first signal TGG according to the ambient light brightness, when the electronic device (display) 1000 is in use, the likelihood of threshold voltage shift of the transistors in the GOP circuits 1001, 1002 due to variations in ambient light brightness can be more effectively reduced, thereby ensuring the reliability of the electronic device (display) 1000.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, having a peripheral region, wherein the electronic device comprises:
a driving circuit, disposed in the peripheral region, the driving circuit comprising:
a first transistor, coupled to a first node;
a second transistor, configured to receive a first voltage and to charge the first node;
a third transistor, having a first terminal coupled to the first node, and a second terminal coupled to ground; and
a fourth transistor, having a first terminal coupled to the first node, and a second terminal coupled to the ground;
wherein at least one of the second transistor, the third transistor, and the fourth transistor comprises a conductive layer, a gate, and a semiconductor layer, and the conductive layer overlaps the gate in a normal direction of the electronic device; and
a temperature sensor, configured to detect a temperature of the driving circuit and to provide the detected temperature to a control chip, wherein the control chip is configured to provide a first signal according to different temperatures;
wherein the conductive layer of the at least one of the second transistor, the third transistor, and the fourth transistor is configured to receive the first signal to adjust a threshold bias voltage of the at least one of the second transistor, the third transistor, and the fourth transistor.

2. The electronic device as claimed in claim 1, wherein the at least one of the second transistor, the third transistor, and the fourth transistor further comprises:
a source, disposed on a first portion of the semiconductor layer, wherein the source is connected to the first portion of the semiconductor layer; and
a drain, disposed on a second portion of the semiconductor layer, wherein the drain is connected to the second portion of the semiconductor layer;
wherein the gate is disposed on a third portion of the semiconductor layer, the gate overlaps the third portion of the semiconductor layer in the normal direction of the electronic device, and the third portion is between the first portion and the second portion.

3. The electronic device as claimed in claim 1, wherein the at least one of the second transistor, the third transistor, and the fourth transistor further comprises:
a first dielectric layer, disposed between the conductive layer and the semiconductor layer; and
a second dielectric layer, disposed between the gate and the semiconductor layer;
wherein the conductive layer is disposed on the first dielectric layer, and the second dielectric layer is disposed on the gate.

4. The electronic device as claimed in claim 2, wherein the at least one of the second transistor, the third transistor, and the fourth transistor further comprises:
a first dielectric layer, disposed between the conductive layer and the semiconductor layer; and
a second dielectric layer, disposed between the gate and the semiconductor layer;
wherein the conductive layer is disposed under the first dielectric layer, and the gate is disposed on the second dielectric layer.

5. The electronic device as claimed in claim 4, wherein the gate, the source, and the drain of at least one of the second transistor, the third transistor, and the fourth transistor are disposed on the second dielectric layer.

6. The electronic device as claimed in claim 4, wherein the at least one of the second transistor, the third transistor, and the fourth transistor further comprises:
a third dielectric layer, disposed on the gate, the source, and the drain.

7. The electronic device as claimed in claim 1, wherein the first signal comprises a negative voltage during an inactive period of the driving circuit, and the first signal comprises a positive voltage during an active period of the driving circuit.

8. The electronic device of claim 1, wherein the electronic device is a display device comprising the driving circuit; and
the temperature sensor is configured to sense a temperature of the display device as the temperature of the driving circuit.

9. The electronic device of claim 1, wherein the control chip comprises a memory storing a relationship between the threshold bias voltage and the temperature.

10. The electronic device of claim 1, wherein the conductive layer comprises indium tin oxide, molybdenum, titanium, or copper.

11. An electronic device, having a peripheral region, wherein the electronic device comprises:
a driving circuit, disposed in the peripheral region, the driving circuit comprising:
a first transistor, coupled to a first node;
a second transistor, configured to receive a first voltage and to charge the first node;
a third transistor, having a first terminal coupled to the first node, and a second terminal coupled to a common ground; and
a fourth transistor, having a first terminal coupled to the first node, and a second terminal coupled to the common ground;
wherein at least one of the second transistor, the third transistor, and the fourth transistor comprises a conductive layer, a gate, and a semiconductor layer, and the conductive layer overlaps the gate in a normal direction of the electronic device; and
a control chip, configured to receive a brightness driving signal representative of a brightness and to provide a first signal according to different brightness levels;
wherein the conductive layer is configured to receive the first signal to adjust a threshold bias voltage of the at least one of the second transistor, the third transistor, and the fourth transistor.

12. The electronic device as claimed in claim 11, wherein the at least one of the second transistor, the third transistor, and the fourth transistor further comprises:
a source, disposed on a first portion of the semiconductor layer, and the source is connected to the first portion of the semiconductor layer;
a drain, disposed on a second portion of the semiconductor layer, and the drain is connected to the second portion of the semiconductor layer;
wherein the gate is disposed on a third portion of the semiconductor layer, the gate overlaps the third portion of the semiconductor layer in the normal direction of the electronic device, and the third portion is between the first portion and the second portion.

13. The electronic device as claimed in claim 12, wherein the at least one of the second transistor, the third transistor, and the fourth transistor further comprises:
a first dielectric layer, disposed between the conductive layer and the semiconductor layer; and
a second dielectric layer, disposed between the gate and the semiconductor layer;
wherein the conductive layer is disposed on the first dielectric layer, and the second dielectric layer is disposed on the gate.

14. The electronic device as claimed in claim 12, wherein the at least one of the second transistor, the third transistor, and the fourth transistor further comprises:
a first dielectric layer, disposed between the conductive layer and the semiconductor layer; and
a second dielectric layer, disposed between the gate and the semiconductor layer;
wherein the conductive layer is disposed under the first dielectric layer, and the gate is disposed on the second dielectric layer.

15. The electronic device as claimed in claim 14, wherein the gate, the source, and the drain of at least one of the second transistor, the third transistor, and the fourth transistor are disposed on the second dielectric layer.

16. The electronic device as claimed in claim 14, wherein the at least one of the second transistor, the third transistor, and the fourth transistor further comprises:
a third dielectric layer, disposed on the gate, the source, and the drain.

17. The electronic device as claimed in claim 11, wherein the first signal comprises a negative voltage during an inactive period of the driving circuit, and the first signal comprises a positive voltage during an active period of the driving circuit.

18. The electronic device of claim 11, wherein the electronic device is a display device comprising the driving circuit;
the control chip is configured to receive the brightness driving signal from an ambient light sensor; and
the ambient light sensor is disposed on a frame of the peripheral region.

19. The electronic device of claim 11, wherein the control chip comprises a memory storing a relationship between the threshold bias voltage and the brightness.

20. The electronic device of claim 11, wherein the conductive layer comprises indium tin oxide, molybdenum, titanium, or copper.
